(19) United States
(12) Patent Application Publication
(10) Pub. No.: US 2018/0277402 A1
(43) Pub. Date: Sep. 27, 2018

(54) PLASMA PROCESSING APPARATUS AND PLASMA PROCESSING METHOD

(71) Applicant: HITACHI HIGH-TECHNOLOGIES CORPORATION, Tokyo (JP)

(72) Inventors: Masatoshi KAWAKAMI, Tokyo (JP); Motohiro TANAKA, Tokyo (JP); Yasushi SONODA, Tokyo (JP); Kohei SATO, Tokyo (JP); Naoki YASUI, Tokyo (JP)

(21) Appl. No.: 15/719,149

(22) Filed: Sep. 28, 2017

(30) Foreign Application Priority Data
Mar. 23, 2017 (JP) 2017-056811

(51) Int. Cl. H01L 21/67; H01J 37/32

(52) U.S. Cl. CPC H01L 21/67069; H01J 2237/334; H01J 37/32715; H01J 37/32449

(57) ABSTRACT

Provided is a plasma processing apparatus or method in which a procedure containing processing steps of supplying a predetermined amount of processing gas into a processing chamber disposed in a vacuum vessel through a gas supply unit, and processing a wafer placed on a sample table disposed in the processing chamber by generating plasma in the processing chamber using the processing gas supplied on each different condition. The procedure includes a first transition step of adjusting and supplying the rare gas to make a pressure of the rare gas equal to a condition of the processing gas used in the former processing step, and a second transition step of adjusting and supplying the rare gas after the first transition step such that a pressure and a flow rate of the rare gas come to be equal to a condition of the processing gas used in the later processing step.

### BACKGROUND OF THE INVENTION

The present invention relates to a plasma processing apparatus and a plasma processing method in which a plate-shape sample such as a semiconductor wafer disposed in a processing chamber in a vacuum vessel is processed by plasma generated in the processing chamber, and relates to a plasma processing apparatus and a plasma processing method in which a sample is processed using plasma generated by switching a plural types of processing gases having different compositions and supplying the processing gas to the processing chamber.

In recent years, a semiconductor element has been miniaturized, and thus an etching accuracy is moving from nm order to A order. A control of an etching process in the A order is very important.

In general, a step time contributing to the etching at the time of consecutive discharging is shortened in order to improve controllability of the etching in an etching procedure. Therefore, there is a need to improve the controllability. Originally, there have been problems of reproducibility and machine differences at the time of consecutive discharging.

In the conventional plasma processing apparatus, there is provided a transition step in which an inert gas is used for an influence caused by mixed etching gases at different step transitions in the consecutive discharging between different steps in order to suppress the reproducibility and the machine differences that are problems in the consecutive discharging. As such a technique, there is known JP 2007-287924 A.

As a conventional technique, there is disclosed a technique of disposing a transition step in which a sample disposed in the processing chamber is processed using a plurality of processing steps in which plasma is generated in a vacuum processing chamber, and an inert gas (for example, Ar gas) which can be used for consecutive discharging of plasma is supplied between processing steps having different condition such as a pressure and a type of the processing gas. Further, the conventional technique discloses that the pressure in the vacuum processing chamber is matched to that of the processing step in the transition step to smoothly change the pressure of the later processing step. In addition, JP 2008-91651 A discloses a technique in which there is provided a gas line which is connected to a gas line for supplying the processing gas to be supplied to the processing chamber and branches off to discharge the processing gas to an exhaust pump for the processing chamber, and in which valves are used to switch a path of processing gas to these gas lines to adjust the supplying of the processing gas into the processing chamber.

### SUMMARY OF THE INVENTION

The conventional technique has a problem because there is no sufficient consideration of the following points.

In other words, in JP 2007-287924 A, a mass flow controller is used to change a flow rate to be matched to a pressure condition of the next step after the flow rate of the inert gas is adjusted to be matched to the pressure in the previous processing step by one mass flow controller when the transition step starts using the inert gas. At that time, it takes a time to control the pressure in a pipe after the flow rate is changed because the flow rate is changed by one mass flow controller. Therefore, there is a problem in performing the transition step in a short time.

In addition, even in an active process step, there is a problem that a switching time is limited to a flow rate changing time in a case where the mass flow controller of the same flow rate and the same gas type is used to change the flow rate. In addition, there are prepared two mass flow controllers of the same flow rate and the same gas type in order to perform the switching. Therefore, there are problems of a cost up, and of securing a mounting space for the mass flow controller.

In addition, the conventional technique includes gas lines, one for introducing a processing chamber and the other for exhausting the gas to a dry pump to make a gas flow rate and a gas pressure with a high reproducibility, a high speed, and a smoothing manner. These lines have been controlled at a high speed of a processing gas by switching valves. In a case where a plurality of gas types are used for switching in a gas supply unit, and when the gases are mixed once by the gas line for exhausting the gas to the dry pump, and the switching is performed on the gas line for introducing the processing chamber, there occurs a voltage fluctuation caused by mixing the gases again, and it takes a time for this control.

In addition, there is a method of closing first a gas line valve of the line for exhausting the gas by the dry pump in order to suppress a deviation (0.1 s) in responsiveness at the time of opening/closing the valve. However, the opening/closing speed of the valve links a solenoid valve and the valve, depends on a length and a thickness of an etching tube. The opening/closing speed is lengthened on a condition of an actual device, and may be near 0.2 s. In the related art, a communication time of a valve opening/closing time device system is not taken into consideration. In addition, there is a command delay deviation of about 0.1 to 0.2 s in the communication time. Therefore, in consideration of a margin of the deviation, the valve is necessarily closed before 0.5 s or more. There is a problem in voltage fluctuation causing a voltage rising in an integrated block.

In addition, in a case where the valve is closed before 0.5 s or more, there are previously needed 1 s for an edge rising of the mass flow controller of the next flowing gas and about 1 s for a voltage control time of the gas line. Therefore, there is a need to start to make the gas flow before 2.5 s or more before the switching, and thus there is a need to realize the switching in a short time equal to or less than 2 s.

In addition, in a case where a valve for high-speed switching of a type of directly mounting the solenoid valve in the valve is used in order to solve the problem in the opening/closing the valve, the switching can be made within about 15 ms. However, since the solenoid valve is directly mounted in the valve, it causes a large space in the gas supply unit as much as the solenoid valve, and a cost for a valve is increased.

In addition, in the related art, there is a need to improve responsiveness until the flow rate in the pipe of the gas line for introducing the processing chamber from the gas supply unit to the chamber. Therefore, the pipe length is necessarily shortened. The pipe length has been shortened by approaching a main body of the gas supply unit to the chamber, but there is a spatial constraint even in the device when the main body of a relatively large gas supply unit is approached to near the chamber. There is a problem in that about 1 m pipe length is necessary for the device.

In addition, when the processing gas is controlled at a high speed as the related art, there are problems in the reproducibility and the machine differences of the flow rate of the processing gas which is controlled at a high speed by switching the gas and a control parameter other than an additional chamber pressure. As parameters for such a control, there are matching of a microwave power for generating plasma, a coil current, and matching of a wafer bias. In addition, there is a transient response time of each control parameter in a step time. Since the transient response time is not able to be controlled, reproducibility is degraded and machine differences are caused.

In the related art, an adjustment time of the microwave power is 0.2 s at maximum, a stable time of the coil current is 2 s at maximum, and the matching of the wafer bias is 0.5 s. On the other hand, when the step time is shortened by a high-speed control of the processing gas, a total ratio occupied by the transient response time is increased. An influence of the process at the transient response time on a processing result is difficult to be adjusted. As a result, there occurs a problem in that a yield of the process is lowered. Further, there is a problem in that a difference (machine difference) between devices having a low reproducibility of the process in a period of such a transient response. The related art fails to consider such problems.

An object of the invention is to provide a plasma processing apparatus or a plasma processing method in which the yield of the process is improved.

The above object is achieved by a plasma processing apparatus or method in which a procedure containing processing steps of supplying a predetermined amount of processing gas into a processing chamber disposed in a vacuum vessel through a gas supply unit, and processing a wafer placed on a sample table disposed in the processing chamber by generating plasma in the processing chamber using the processing gas supplied on each different condition. The procedure includes a transition step in which a rare gas is supplied into the processing chamber between two former and later processing steps. The transition step includes a first transition step of adjusting and supplying the rare gas to make a pressure of the rare gas equal to a condition of the processing gas used in the former processing step, and a second transition step of adjusting and supplying the rare gas after the first transition step such that a pressure and a flow rate of the rare gas come to be equal to a condition of the processing gas used in the later processing step.

According to the invention, it is possible to reduce degradation in reproducibility of a process performance and the machine differences which are the problems at the time of a short-time step, and the short-time step can be realized.

### BRIEF DESCRIPTION OF THE DRAWINGS

FIG. 1 is a vertical cross-sectional view schematically illustrating a configuration of a plasma processing apparatus according to an embodiment of the invention;

FIG. 2 is a block diagram schematically illustrating a configuration of a matching circuit provided in the embodiment illustrated in FIG. 1;

FIG. 3 is a table illustrating some of conditions in a plurality of procedures of an etching process performed in the embodiment illustrated in FIG. 1;

FIG. 4 is a graph illustrating an operational flow of the procedures illustrated in FIG. 3;

FIG. 5 is a diagram schematically illustrating a flow of gas in Processing step A performed by the plasma processing apparatus according to the embodiment of FIG. 1;

FIG. 6 is a diagram schematically illustrating a flow of gas in Transition step 1 performed by the plasma processing apparatus according to the embodiment of FIG. 1;

FIG. 7 is a diagram schematically illustrating a flow of gas in Transition step 2 performed by the plasma processing apparatus according to the embodiment of FIG. 1; and

FIG. 8 is a diagram schematically illustrating a flow of gas in Processing step B performed by the plasma processing apparatus according to the embodiment of FIG. 1.

### DESCRIPTION OF THE EMBODIMENTS

Hereinafter, embodiments of the invention will be described using the drawings. The following embodiments will be described about a plasma processing apparatus and a processing procedure thereof. The plasma processing apparatus includes a processing chamber which is connected to a vacuum evacuation device to depressurize the inner portion and is sealed by a dielectric window and the vacuum vessel, a substrate electrode on which a processing target material is mountable, a shower plate which is provided to face the substrate electrode, a gas supply unit which supplies a processing gas into the processing chamber, a high-frequency wave introducing unit which is used to introduce an electromagnetic wave from the dielectric window to generate plasma, and a unit which generates a magnetic field to generate the plasma. A plasma processing apparatus is provided with a gas switching mechanism apart from the gas supply unit on a first gas supply line through which the processing gas is supplied from the gas supply unit to a depressurized processing chamber through the shower plate.

The gas switching mechanism of this embodiment is configured by nine valves for switching two disposal gas lines which are connected two gas intake lines for connection and a roughly-pumping exhaust line, a chamber intake gas line, a pressure gauge for measuring pressure, two pressure gauges for measuring the pressures of two disposal gas lines, and two pressure controllers for controlling the pressures of the chamber intake gas line and the disposal gas line to be equal. With this mechanism, gas is caused to flow to the disposal gas line in advance to make normal flowing before the respective conditions start, so that the pressure of the disposal gas line can be adjusted to be equal to the pressure of the chamber intake gas line so as to make a smooth connection without causing fluctuation.

In addition, the gas switching mechanism is separately provided in the gas supply unit, so that it is possible to use a high-speed switching valve in which a solenoid valve is mounted without wasting space in the gas supply unit. In addition, with the use of high-speed switching valve, it is possible to reduce time for the switching step without shifting the open/close switching timing in consideration of a response delay of the valve.

In addition, it is sure to perform the gas switching using a transition step using an inert gas and an additional mass flow controller for the transition step at the time of high-speed switching. Therefore, even in a case where the same gas flow rate of the same type of gas is used in a processing step, a flow rate variation is not taken into consideration, and thus it is possible to reduce time for the processing step. Further, since there is no need to prepare two mass flow controllers of the same gas type and the same flow rate in the gas supply unit, it is possible to suppress a product cost low.

In addition, since the gas supply unit operates normally, there is no need to replace the valve in the gas supply unit with a high-speed switching expensive valve. Further, the high-speed switching valve is used only for the gas switching mechanism, so that it is possible to suppress a product cost low.

In addition, since a gas switching unit is also disposed on the downstream side of the gas supply unit, the gas switching is performed after the gas flows normally in a state where a plurality of gases are mixed even in a case where a plurality of gas types are used. There is no need to mix gases again when the gas is switched unlike the related technique. Further, it is possible to suppress a pressure variation caused in a processing gas pipe at that time.

In an actual operation of the processing step, the transition step is used between Processing step A and Processing step B. The transition step is divided into two parts, the first half and the latter half. In Transition step 1 of the first half, a microwave power, a coil current, and a processing chamber pressure of the previous processing step condition A are maintained. A wafer bias power is turned off, and the gas is switched to argon or an inert gas of which the gas flow rate is the same degree. Next, in Transition step 2 of the latter half, the condition is switched to a microwave power, a coil current, and a processing pressure of the next processing step condition B while keeping the wafer bias power turned off. The gas is switched to Ar or an inert gas of which the gas flow rate is the same degree as that of the processing step condition B. Since the microwave power, the coil current, the processing chamber pressure, and the gas flow rate are switched in the transition step, it is possible to reduce an influence on reproducibility caused from a matching time of the microwave power, a control time of the coil current, and a transient response time of these components, and reduce an influence of machine differences. In addition, a transient response is suppressed by setting a matching value of a wafer bias matching circuit to a value of the next processing step at the time of an OFF state.

It is possible to reduce degradation in reproducibility of a process performance and the machine differences which are the problems of the related technique, and it is possible to realize a short-time step.

### First Embodiment

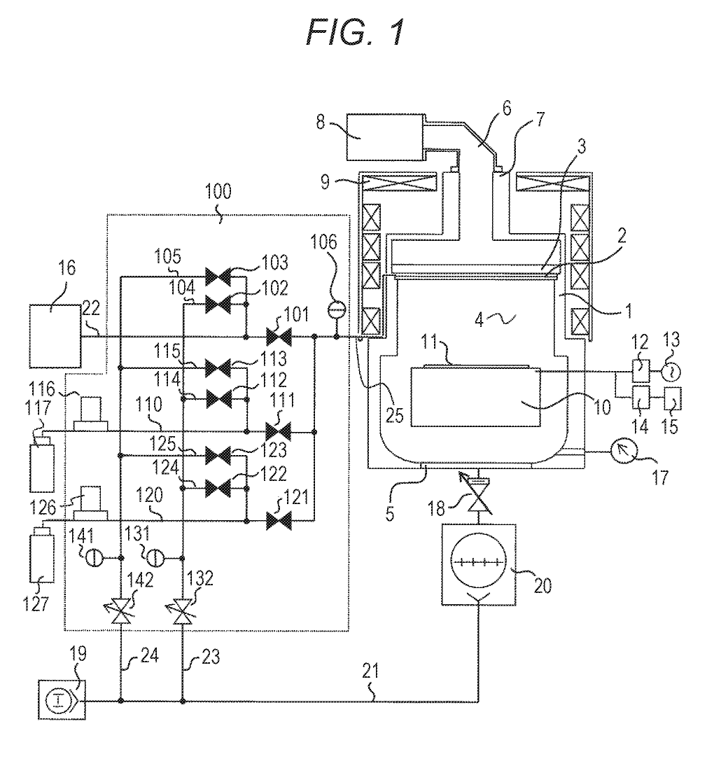

Hereinafter, an embodiment of the invention will be described using FIG. 1. FIG. 1 is a diagram illustrating a plasma processing apparatus according to the embodiment of the invention. In particular, the plasma processing apparatus of this embodiment is an apparatus which performs etching using a microwave ECR (Electron Cyclotron Resonance).

FIG. 1 is a vertical cross-sectional view schematically illustrating a configuration of the plasma processing apparatus according to the embodiment of the invention. In the drawing, the plasma processing apparatus according to the embodiment of the invention includes a vacuum vessel 1 equipped with a processing chamber 4 in which a sample table 10 for placing and holding a wafer 11 (a plate-shape processing target sample) is disposed and the plasma is generated to process the wafer 11, an exhaust device equipped with a turbo molecular pump 20 which evacuates the inner portion of the processing chamber 4 disposed on the lower side, and a plasma generating unit surrounds the upper side and a circumference of the processing chamber 4 in the outer portion of the vacuum vessel 1 to generate an electric field or a magnetic field for the plasma to be supplied into the processing chamber 4. The plasma processing apparatus performs a procedure of etching the wafer 11 to manufacture a semiconductor device.

The vacuum vessel 1 of the plasma processing apparatus of this embodiment has a cylindrical shape or a shape similar to a cylindrical shape, and includes a dielectric window 3 (for example, a material such as quartz) configured by a cylindrical side wall and a disk-like dielectric material which is a lid member disposed in the upper side to be freely opened and is transmissive to the electric field or the magnetic field. The dielectric window 3 and the upper end of the side wall are connected with a seal member such as an O-ring therebetween. In a state where the dielectric window 3 is connected, the inner and outer sides of the processing chamber 4 of the inner portion of the vacuum vessel 1 are tightly sealed and secured, and the vacuum vessel 1 is configured such that the dielectric window 3 is disposed as a part member of the upper portion.

In the lower side of the dielectric window 3, a shower plate 2 is disposed which is a disk-like dielectric member (for example, quartz or a material containing ceramics such as yttria) which serves as a ceiling surface of the processing chamber 4 of the inner portion of the vacuum vessel 1 and is provided with a plurality of through holes are disposed to supply a processing gas from the upper side into the processing chamber 4. A buffering space is disposed between the shower plate 2 and the dielectric window 3, and the processing gas supplied from the through hold into the processing chamber 4 is supplied, diffused, and dispersed to fill the space.

The inner portion of the buffering space is linked to a gas supply unit 16 which supplies the processing gas to the plasma processing apparatus, and an etching gas supplied from the gas supply unit 16 circulates the inner portion through an etching gas supply line 22 which includes a gas supply pipe connected to the vacuum vessel 1. In addition, there are provided a gas switching unit 100 between the etching gas supply line 22 and a chamber intake gas line 25 through which the processing gas is supplied from a gas supply unit 16 to the depressurized processing chamber through the shower plate 2. A variable conductance valve 18, the turbo molecular pump 20, and a dry pump 19 are disposed on the lower side of the vacuum vessel 1, and are connected with the processing chamber 4 through a vacuum exhaust port 5 which is disposed in the bottom of the processing chamber 4 in the vacuum vessel 1.

As a high-frequency wave introducing unit which emits the electromagnetic wave, a waveguide pipe 6 (or antenna) is disposed on the upper side of the dielectric window 3 in order to propagate the power for generating the plasma to the processing chamber 4.

The waveguide pipe 6 is configured such that a tubular portion of a cylindrical shape of the waveguide pipe 6 extending in the vertical direction is linked to one end of a tubular portion of a rectangular shape in sectional view which extends in the horizontal direction in the upper end, and is changed in direction. Further, an electromagnetic wave generating power source 8 is disposed on the other end of the tubular portion of the rectangular shape in sectional view in order to propagate the electromagnetic wave into the waveguide pipe 6. The frequency of the electromagnetic wave is not particularly limited, and in this embodiment a microwave of 2.45 GHz may be used.

A magnetic-field generating coil 9 which generates a magnetic field is disposed on the upper side of the dielectric window 3 and the outer peripheral side of the side wall of the cylindrical portion of the vacuum vessel 1 (the outer peripheral portion of the processing chamber 4). The waveguide pipe 6 and the electric field which are oscillated by the electromagnetic wave generating power source 8 and introduced into the processing chamber 4 through a cavity resonator 7, the dielectric window 3, and the shower plate 2 are mutually interacted with the magnetic field which is generated by the magnetic-field generating coil 9 supplied with a DC power and is introduced into the processing chamber 4 so as to excite particles of the etching gas, and thus the plasma is generated in a space on the lower side of the shower plate 2 in the processing chamber 4. In addition, the sample table 10 disposed to face the lower surface is disposed on the lower side of the shower plate 2 which is the lower portion in the processing chamber 4 in this embodiment.

The sample table 10 has a substantially-cylindrical shape in this embodiment, and a dielectric film (not illustrated) formed by spraying in the upper surface where the wafer 11 of the processing target is placed. A DC power source 15 is connected to at least one electrode of a film shape which is disposed in the inner portion of the dielectric film through a high-frequency filter 14, so that the DC power can be supplied. Further, a conductive base material of a disk-like shape is disposed in the inner portion of the sample table 10, and a high-frequency power source 13 is connected through a matching circuit 12.

Further, the plasma processing apparatus of this embodiment includes a control unit (not illustrated) which is connected to transfer signals with respect to the portions of the vacuum vessel 1, the exhaust device, the plasma generating unit, the gas switching unit 100, the matching circuit 12, and the high-frequency power source 13. In the plasma processing apparatus of this embodiment, a software program stored in a storage device such as a hard disk, a CD-ROM, a RAM, or a ROM in the control unit is read out in a procedure of etching the wafer 11 described below. A command signal calculated by an operation of a calculator such as a semiconductor microprocessor on the basis of an algorithm described in the software program is transmitted to the respective portions so as to adjust the operations thereof, and the etching process of the wafer 11 is performed. The control unit is a unit to which an interface for the communication with the storage device and the calculator is connected to communicate, and may be configured by one or a plurality of devices.

In such a plasma processing apparatus, the wafer 11 in which a film structure of a plurality of laminated film layers containing a resin mask layer is formed in advance is conveyed to the inner portion of the processing chamber 4 in an unprocessed state where the film layer of the processing target of the film structure is not processed, and is held on the upper surface of the sample table 10. The film layer of the processing target is etched using the mask formed in the processing chamber 4. More specifically, while not illustrated in the drawing, the unprocessed wafer 11 is transferred by a conveyance chamber of a vacuum conveyance containing equipped with a conveyance unit such as a robot arm in the conveyance chamber which is linked to the side wall of the vacuum vessel 1 and depressurized, and is carried into the processing chamber 4 through a gate which is the through hole disposed in the side wall of the vacuum vessel 1.

The unprocessed wafer 11 held on the conveyance unit is placed and transferred on the upper end of a plurality of pins which are disposed in the sample table 10 and protrude upward from the upper surface of the sample table 10. In a state where the conveyance unit such as a robot arm is carried out from the processing chamber 4 and a gate valve (not illustrated) is air-tightly closed, the pins fall down into the sample table 10 and contained therein. The wafer 11 transferred to the sample table 10 is absorbed onto the upper surface of the sample table 10 by an electrostatic force of a DC voltage applied from the DC power source 15.

Next, an etching gas (a predetermined processing gas) is supplied from the gas supply unit 16 into the processing chamber 4. A pressure of the inner portion of the processing chamber 4 is detected by a pressure gauge 17, and the result is fed back, so that the operation of the variable conductance valve 18 is adjusted and the inner portion of the processing chamber 4 is adjusted to be a pressure suitable for the processing. In this state, the electric field and the magnetic field are supplied into the processing chamber 4 to dissociate and ionize atoms or molecules of the processing gas supplied to the space in the processing chamber between the sample table 10 and the shower plate 2 in the processing chamber 4 so as to generate the plasma in the processing chamber 4. In a state where the plasma is generated, a high-frequency power of a predetermined frequency is applied from the high-frequency power source 13 to the sample table 10, a bias potential is formed on the upper side of the wafer 11, charged particles in the plasma are attracted to the surface of the wafer 11 according to a potential difference between the bias potential and the potential of the plasma, and the particles come into conflict with the film structure of the surface of the wafer 11, so that the processing target film is etched.

In the etching process of this embodiment, a plurality of etching procedures are switched on a condition where at least one processing target film layer of the film structure of the upper surface of the wafer 11 is differently processed as time goes by after the processing. Further, in this example, at least one transition procedure (transition step) is performed to change the processing condition from the former procedure to the later procedure between two former and later procedures (processing steps) as time goes by.

When the processing of the film structure is performed in a predetermined time period and the end of the processing is detected, the supplying of the high-frequency power from the high-frequency power source for a bias potential to the disk-like electrode of the inner portion of the sample table 10 is stopped, and the etching process is stopped. Then, the absorption caused by the electrostatic force is neutralized and released. Thereafter, the plurality of pins contained in the inner portion of the same table 10 are driven to move upward, and the wafer 11 placed on the upper end of the plurality of pins is separated from the upper surface of the sample table 10 and held. In this state, the gate valve operates to open the gate, and the processed wafer 11 is transferred to the upper side of the upper surface of the conveyance device which enters the processing chamber 4 again through the gate. The conveyance device is retreated out from the processing chamber 4 to carry out the wafer 11 to the outside, and the gate is closed again.

Next, the description will be given about the gas switching unit 100 which includes the gas switching mechanism provided in the plasma processing apparatus of this embodiment.

The gas switching unit 100 of this embodiment includes an etching gas supply line 22 which is a first gas supply line connecting the gas supply unit 16 and the vacuum vessel 1, and a first valve 101 which is provided on the etching gas supply line 22. Further, there are provided with a first disposal gas line 23 which is branched from the etching gas supply line 22 and is disposed to be connected to an exhaust line 21 which connects the turbo molecular pump 20 for exhausting the processing chamber 4 and the inlet of the roughly-pumping dry pump 19 disposed on the downstream side of the flow from the exhaust port, a first bypass line 104 which connects the etching gas supply line 22 between the first valve 101 and the gas supply unit 16 and the first disposal gas line 23, and a second valve 102 which is provided on the first bypass line.

Furthermore, there are provided a second disposal gas line 24 which is branched from the etching gas supply line 22 and is connected to the exhaust line 21, a second bypass line 105 which is connected to the etching gas supply line 22 between the first valve 101 and the gas supply unit 16 and the second disposal gas line 24, and a third valve 103 which is provided on the second bypass line 105. The first disposal gas line 23 and the second disposal gas line 24 are lines for discharging the processing gas flowing in the etching gas supply line 22 to the outside of the plasma processing apparatus through the dry pump 19.

In addition, the gas switching unit 100 includes a first transition-step gas supply source 117 which supplies a rare gas or an inert gas such as argon in the processing chamber 4 in the transition step, a second gas supply line 110 in which a first transition-step gas supplied from the first transition-step gas supply source 117 circulates and which connects the first transition-step gas supply source 117 and the etching gas supply line 22, and a mass flow controller 116 for the first transition-step gas which is disposed on the second gas supply line 110 and adjusts a flow rate or a speed of the first transition-step gas. The second gas supply line 110 is connected to the etching gas supply line 22 between the first valve 101 and the chamber intake gas line 25.

Further, there are included a fourth valve 111 which is provided on the second gas supply line 110, a third bypass line 114 which connects the second gas supply line 110 and the first disposal gas line 23 in order to discharge the first transition-step gas supplied from the second gas supply line 110 toward the dry pump 19, and a fifth valve 112 which is provided on the third bypass line 114. Furthermore, there are included a fourth bypass line 115 which connects the second gas supply line 110 and the second disposal gas line 24 and a sixth valve 113 which is provided on the fourth bypass line 115 in order to discharge the first transition-step gas supplied from the first transition-step gas supply source 117 toward the dry pump 19.

In addition, there are included a second transition-step gas supply source 127 which supplies a rare gas or an inert gas such as argon into the processing chamber 4 in the transition step, a third gas supply line 120 in which a second transition-step gas supplied from the second transition-step gas supply source 127 circulates and which connects the second transition-step gas supply source 127 and the etching gas supply line 22, and a mass flow controller 126 for the second transition-step gas which is disposed in the third gas supply line 120 and adjusts a flow rate or a speed of the second transition-step gas. The third gas supply line 120 is connected to the etching gas supply line 22 between the first valve 101 and the chamber intake gas line 25.

Further, there are included a seventh valve 121 which is provided on the third gas supply line 120, a fifth bypass line 124 which connects the third gas supply line 120 and the first disposal gas line 23 in order to discharge the second transition-step gas supplied from the third gas supply line 120 toward the dry pump 19, and an eighth valve 122 which is provided on the fifth bypass line 124. Furthermore, there are included a sixth bypass line 125 which connects the third gas supply line 120 and the second disposal gas line 24, and a ninth valve 123 which is provided on the sixth bypass line 125 in order to discharge the second transition-step gas supplied from the second transition-step gas supply source 127 toward the dry pump 19.

In addition, in the gas switching unit 100, the pressure gauge is disposed in each of the gas lines, a pressure gauge 106 for the chamber intake gas line is disposed in the chamber intake gas line 25, a pressure gauge 131 for the first disposal gas line is disposed on the first disposal gas line 23, and a pressure gauge 141 for the second disposal gas line is disposed in the second disposal gas line 24.

In addition, a variable conductance valve 132 is disposed in the first disposal gas line 23, and a variable conductance valve 142 is disposed in the second disposal gas line 24. These variable conductance valves 132 and 142 each perform an operation in which an opening degree of the valve is changed to increase/decrease conductance such as a cross-sectional area of the flow channel and a shape of the flow channel in the pipe such that the values detected by the pressure gauge 131 for the first disposal gas line and the pressure gauge 141 for the second disposal gas line each become the same value as that detected by the pressure gauge 106 for the chamber intake gas line. Further, the gases supplied to the first disposal gas line 23 and the second disposal gas line 24 are discharged to the outside of the plasma processing apparatus by the dry pump 19 through the exhaust line 21.

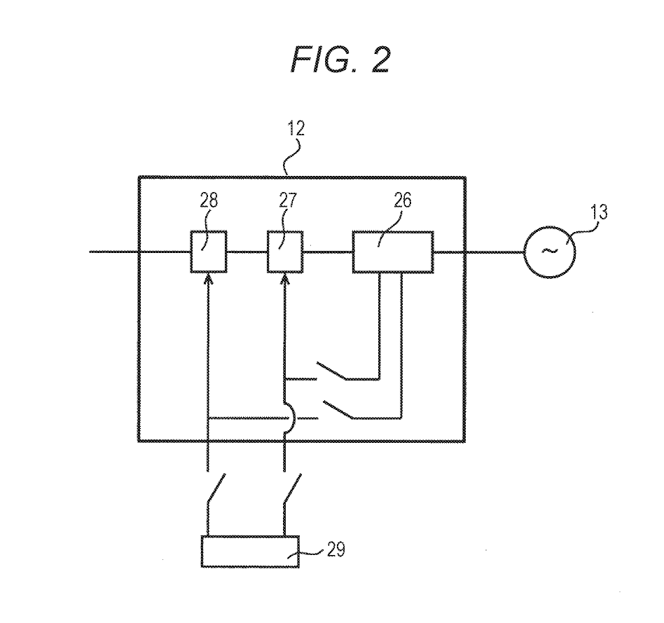

Next, the matching circuit 12 equipped in the plasma processing apparatus of this embodiment will be described using FIG. 2. FIG. 2 is a block diagram schematically illustrating a configuration of the matching circuit provided in the embodiment illustrated in FIG. 1.

As illustrated in, the matching circuit 12 of this example is disposed on a power supply path connecting the high-frequency power source 13 and a conductive electrode embedded in the sample table 10. An impedance controller 26, a first matching variable element 27, and a second matching variable element 28 are electrically connected in this order to the high-frequency power source 13. In addition, the matching circuit 12 is connected to an impedance external indicator 29 through a switch.

The switch disconnects or connects the electrical connection between the impedance external indicator 29 and each of the first matching variable element 27 and the second matching variable element 28. Further, the matching circuit 12 also includes a switch which disconnects or connects the electrical connection between the impedance controller 26 and the impedance external indicator 29. With these switches, the impedance controller 26 and the impedance external indicator 29 can be switched. In a case where the impedance controller 26 is connected, the impedance controller 26 adjusts the first matching variable element 27 and the second matching variable element 28 to be matched while monitoring a deviation in impedance. In a case where the impedance external indicator 29 is connected, the first matching variable element 27 and the second matching variable element 28 are adjusted such that the impedance external indicator 29 indicates an arbitrary value. With these switches, the switching can be made when the high-frequency power source 13 is turned off.

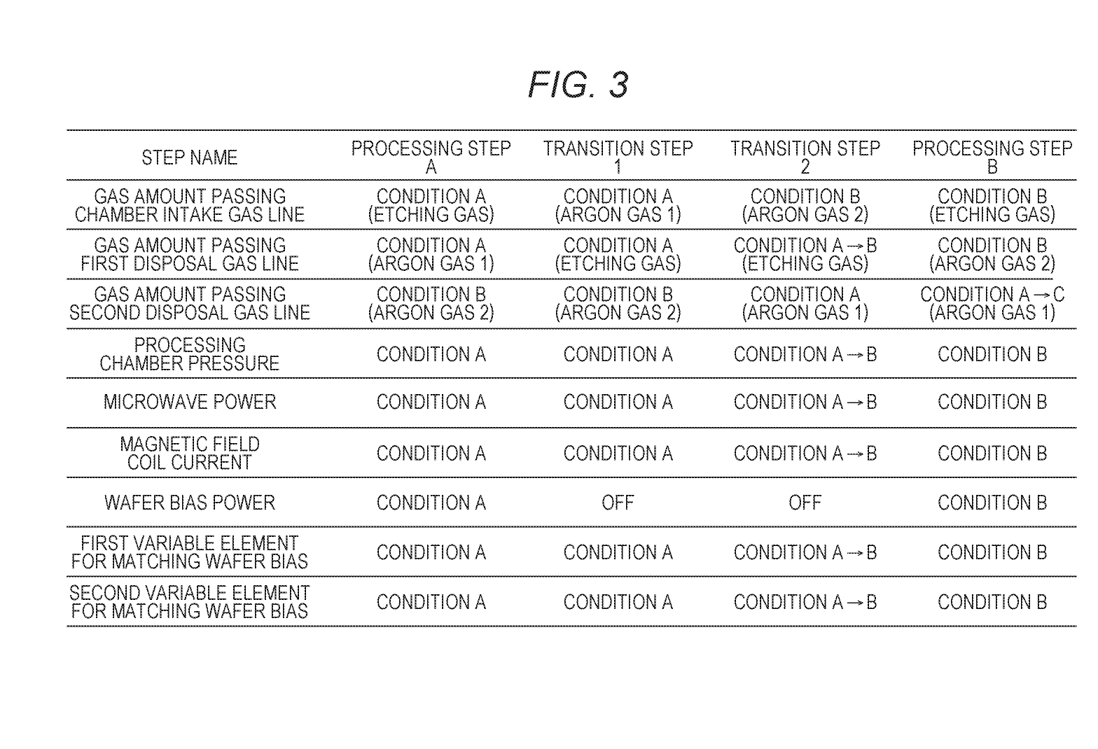

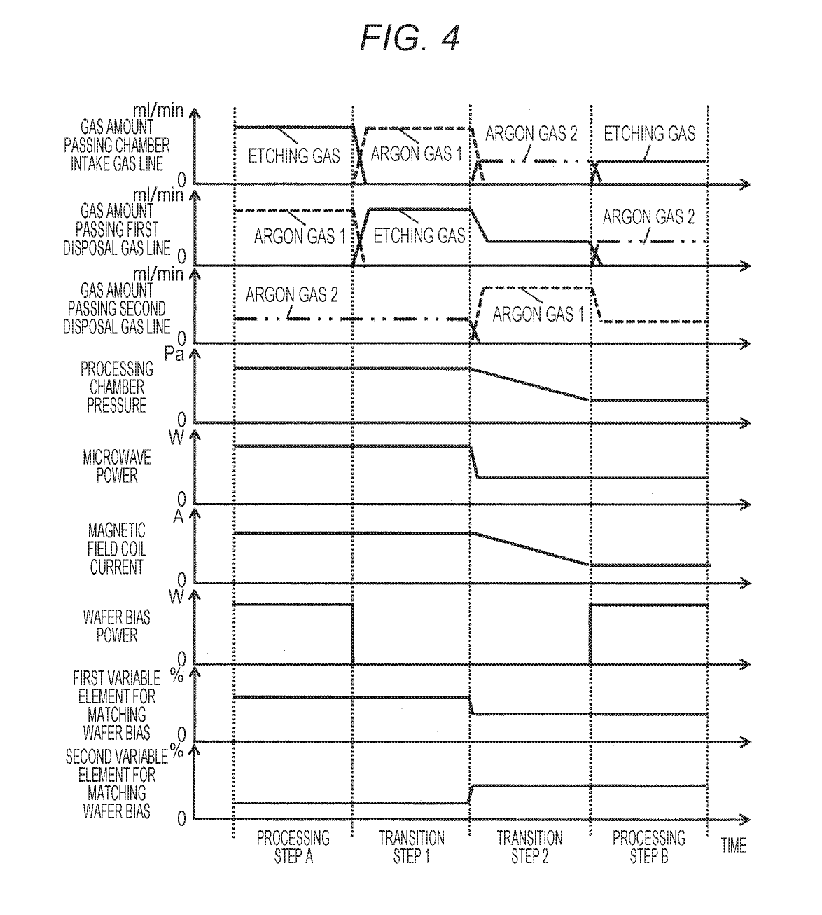

Next, a procedure of the etching process of this embodiment will be described using FIGS. 3 and 4. FIG. 3 is a table illustrating some conditions in each of a plurality of procedures of the etching process of the embodiment illustrated in FIG. 1. FIG. 4 is a graph illustrating an operational flow of the procedure illustrated in FIG. 3.

As described above, in this embodiment, there is provided the transition step in which the condition different in these steps is changed from the former value to the later value between two former and later processing steps of processing at least one processing target film layer. In particular, the transition step is divided into two steps (Transition step 1 and Transition step 2) which are continuously performed from the former to the later.

In Transition step 1, among the processing conditions, a power (microwave power) to generate an electric field of a microwave supplied from the electromagnetic wave generating power source 8, a current (magnetic field coil current) to generate a magnetic field supplied to the magnetic-field generating coil 9, and a voltage (processing chamber pressure) in the processing chamber 4 are maintained at those in Processing step A in which the value is the same as that of the former processing step. In other words, in Transition step 1, the power (wafer bias power) which is supplied to the sample table 10 to form a bias is not supplied (turned off). Further, the gas circulating the chamber intake gas line 25 is switched to argon or an inert gas, and the flow rate is set to be the same as that of the processing gas of Processing step A.

In Transition step 2 performed next, among the processing conditions, the wafer bias power is kept stopped (OFF), and the values of the microwave power, the magnetic field coil current, and the processing chamber pressure are changed to those of the processing condition of Processing step B. Further, the flow rate of argon or an inert gas circulating the chamber intake gas line 25 is changed to be the same value as that of the processing gas of Processing step B.

In this way, between Transition steps 1 and 2, the values of the processing condition such as the microwave power, the magnetic field coil current, the processing chamber pressure, and the flow rate of the gas supplied to the processing chamber 4 are changed from the settings of the former condition of the processing step to those of the later condition in the processing steps before and after the transition step. Therefore, a time taken until a magnitude of the microwave power is changed to be matched, and a time taken until the values of the magnetic field coil current and the processing chamber pressure are changed to be stable are reduced, so that a throughput of the processes is improved. Furthermore, the reproducibility of a profile of the transient response of each condition in a so-called transient response time taken until the setting value starts to be changed to a value of an actual condition after receiving a command signal of changing the setting value or until the value becomes a magnitude within a predetermined allowable fluctuation range is improved. The machine differences of such a transient response are reduced, and a throughput of processes is improved. In addition, in the matching of the wafer bias power, a matching value of each of the first matching variable element 27 and the second matching variable element 28 in Processing step B is acquired in advance in Transition step 2 where the OFF state of the wafer bias power is maintained. Then, the wafer bias power is adjusted to be the matching value before Processing step B starts, so that an influence of the transient response is suppressed.

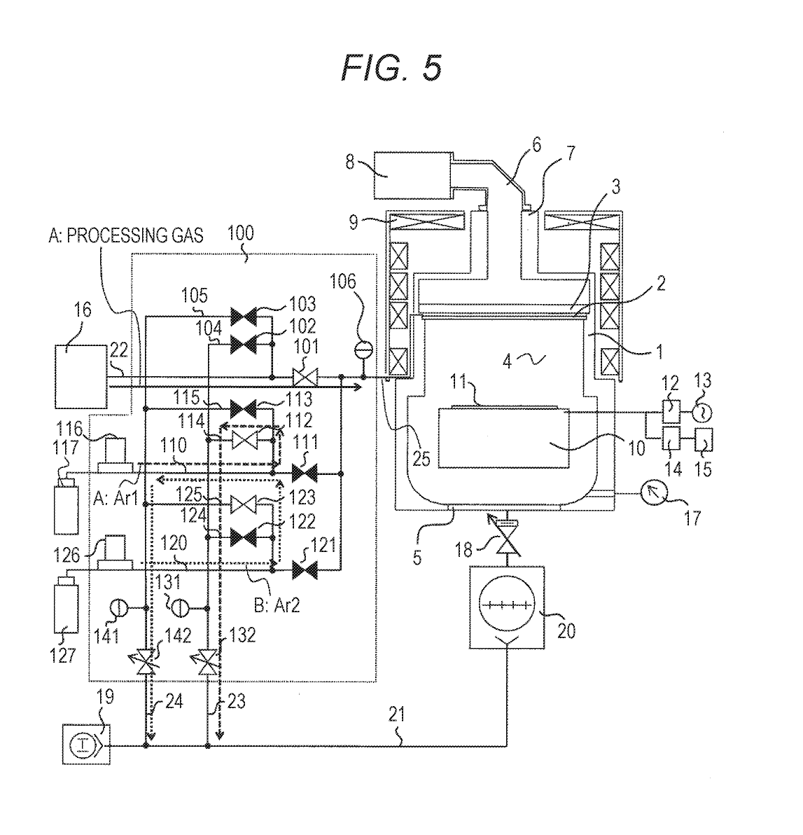

Next, a flow of the gas in the gas switching unit 100 in each step illustrated in FIG. 3 will be described using FIGS. 5 to 8. In these drawings, argon (Ar) is used as an inert gas. The argon gas supplied from the mass flow controller 116 for the first transition-step gas is denoted as Argon gas 1 (Ar1), and the argon gas supplied from the mass flow controller 126 for the second transition-step gas is denoted as a Argon gas 2 (Ar2). In addition, variations of the gas flow rate of the first disposal gas line 23 and the gas flow rate of the second disposal gas line 24 in the etching process of the wafer 11 performed in the steps illustrated in these drawings are illustrated in FIG. 3, and a flow of the processing operation is illustrated in FIG. 4.

FIG. 5 illustrates a gas flow in the gas switching unit 100 of Processing step A. FIG. 5 is a diagram schematically illustrating a gas flow in Processing step A performed by the plasma processing apparatus according to the embodiment of FIG. 1.

In this drawing, when Processing step A starts, the first valve 101 on the etching gas supply line 22 is opened on the basis of a command signal from the control unit (not illustrated), and the etching gas as the processing gas used in Condition A of the step from the gas supply unit 16 is adjusted such that the flow rate or the speed becomes the value of Condition A by the mass flow controller disposed in the gas supply unit 16 and is supplied to the processing chamber 4 through the chamber intake gas line 25. At this time, the pressure gauge 106 for the chamber intake gas line senses the pressure of the chamber intake gas line 25, and the sensing result is transmitted to the control unit to detect a pressure value. Further, the fifth valve 112 is opened in parallel at a time when the first valve 101 is opened and at a time which is actually considered as the same time, and Argon gas 1 (Ar1) of the same flow rate as the etching gas of Condition A in the mass flow controller 116 for the first transition-step gas is supplied to the first disposal gas line 23 through the second gas supply line 110 and the third bypass line 114.

In addition, the ninth valve 123 is opened in parallel substantially at the same time when the first valve 101 is opened, Argon gas 2 (Ar2) adjusted to have the same flow rate as the etching gas of Condition B which is the processing condition in Processing step B in the mass flow controller 126 for the second transition-step gas is supplied to the second disposal gas line 24 through the third gas supply line 120 and the fifth bypass line. The gas starts to be supplied to the first disposal gas line 23 of Argon gas 1 at a time which contains a time taken until the flow rate or the speed of Argon gas 1 comes to be equal to Condition A during a period of Processing step A. The flow rate or the speed of Argon gas 1 in the first disposal gas line 23 is maintained at the value of Condition A during a period of Processing step A. The supplying of Argon gas 2 to the first disposal gas line 23 starts at a time which can contain a time taken until the flow rate or the speed of Argon gas 2 comes to be equal to Condition B during the period of Processing step A or Transition step 1. During the period of Processing step A and Transition step 1, the flow rate or the speed of Argon gas 2 in the second disposal gas line 24 is maintained at the value of Condition B.

In other words, the pressure in the first disposal gas line 23 is sensed by the pressure gauge 131 for the first disposal gas line when Argon gas 2 circulates, and a signal indicating the sensing result is transmitted to the control unit to detect the pressure. The command signal from the control unit is transmitted to the variable conductance valve 132 on the basis of the detection result. With the operation of the variable conductance valve 132 based on the transmitted command signal, the gas pressure in the first disposal gas line 23 is sensed by the pressure gauge 106 for the chamber intake gas line, and adjusted to be the same value as the detected result. Similarly, the pressure in the second disposal gas line 24 is sensed by the pressure gauge 141 for the second disposal gas line, and transmitted to the control unit to detect the pressure. The variable conductance valve 142 is driven on the basis of the command signal from the control unit to adjust such that the pressure in the second disposal gas line 24 comes to be equal to the value of the pressure gauge 106 for the chamber intake gas line.

In this state, Processing step A is performed. A signal indicating an end point detected by an end-point determination unit (not illustrated) is transmitted to the control unit to determine the end point, and Processing step A is ended. Further, Transition step 1 starts on the basis of the command signal from the control unit.

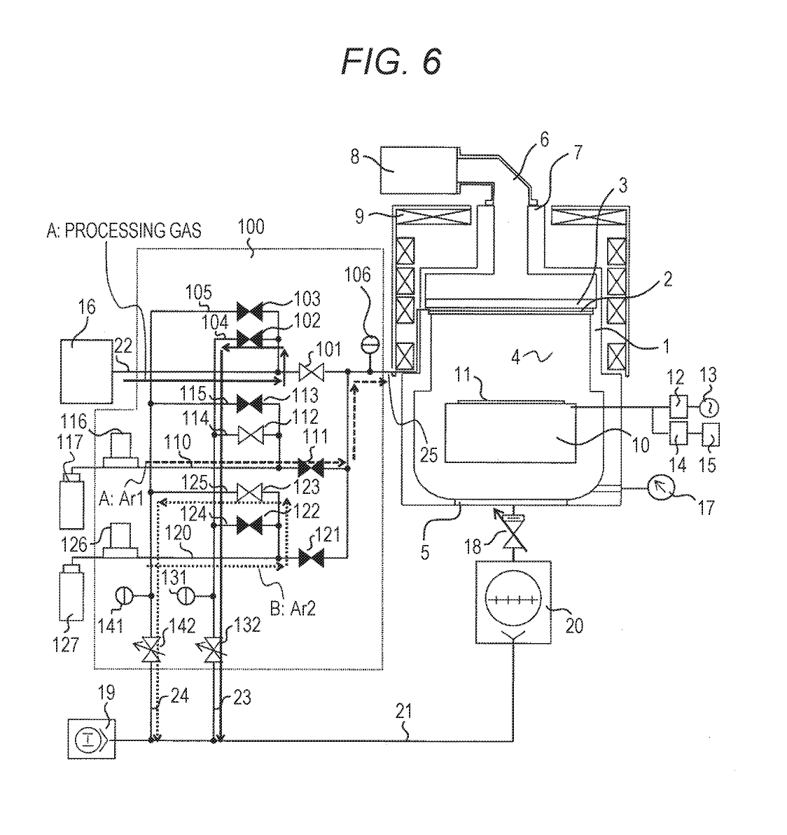

FIG. 6 illustrates a gas flow in the gas switching unit 100 of Transition step 1. FIG. 6 is a diagram schematically illustrating a gas flow in Transition step 1 performed by the plasma processing apparatus according to the embodiment of FIG. 1.

When Transition step 1 starts, the first valve 101 on the etching gas supply line 22 is closed and the second valve 102 is opened on the basis of a command from the control unit. Then, the etching gas from the gas supply unit 16 of Condition A is supplied to the first disposal gas line 23 through the first bypass line 104. Substantially at the same time with the above operation, the fifth valve 112 is closed, the fourth valve 111 is opened. Therefore, Argon gas 1 of which the flow rate or the speed is adjusted to be the same or a similar value actually considered as equal as that of the etching gas of Condition A by the mass flow controller 116 for the first transition-step gas is supplied to the processing chamber 4 through the second gas supply line 110 and the chamber intake gas line 25 connected to the second gas supply line.

Such a state is maintained during Transition step 1, and Argon gas 1 is supplied to the processing chamber 4 through the second gas supply line 110. In addition, during the processing step 1, the operation of the variable conductance valve 142 is adjusted on the basis of the command signal from the control unit to which the sensing result of the pressure gauge 141 of the second disposal gas line is transmitted. The pressure of the second disposal gas line 24 is adjusted to have the same or similar value to the detected value of the pressure gauge 106 for the first gas supply line. When the control unit detects or determines that a predetermined period elapses after Transition step 2 starts, Transition step 1 is stopped on the basis of the command signal from the control unit and Transition step 2 starts.

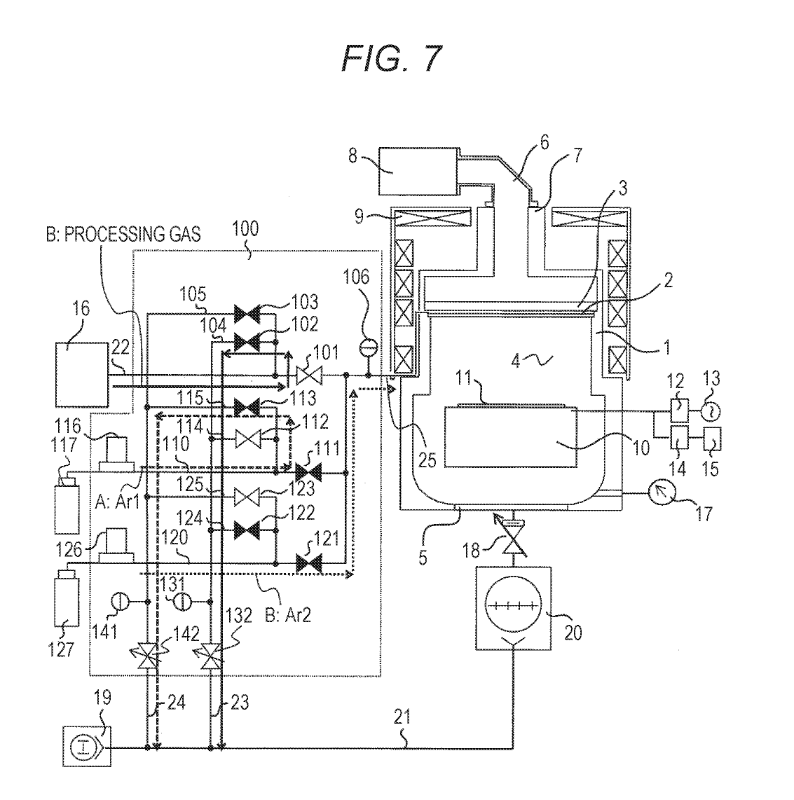

FIG. 7 illustrates a gas flow in the gas switching unit 100 of Transition step 2. FIG. 7 is a diagram schematically illustrating a gas flow in Transition step 2 performed by the plasma processing apparatus according to the embodiment of FIG. 1.

In this drawing, when Transition step 2 starts, the fourth valve 111 is closed, the sixth valve 113 is opened on the basis of the command signal from the control unit, and Argon gas 1 of which the flow rate or the speed is adjusted to be the same value as that of the etching gas of Condition A by the mass flow controller 116 for the first transition-step gas is supplied to the second disposal gas line 24 through the second gas supply line 110 and the fourth bypass line 115. At this time, the operation of the variable conductance valve 142 is adjusted on the basis of the command signal from the control unit, and the pressure in the second disposal gas line 24 is adjusted to be the same value or substantially equal to that of the chamber intake gas line 25 detected from the pressure gauge 106 for the chamber intake gas line.

In addition, the ninth valve 123 is closed and the seventh valve 121 is opened in parallel at the same time or actually the same time, and Argon gas 2 (Ar2) of which the flow rate or the speed is adjusted to be the same value or substantially equal to that of the etching gas of Condition B which is the processing condition in Processing step B by the mass flow controller 126 for the second transition-step gas, and supplied to the processing chamber 4 through a third gas supply line 120 and the chamber intake gas line 25 connected to the third gas supply line. At this time, the operation of the variable conductance valve 142 is adjusted on the basis of the command signal from the control unit according to the result detected by the control unit from the signal indicating the sensing result of the pressure gauge 141 for the second disposal gas line, and the pressure in the second disposal gas line 24 is adjusted to be the same value or equal to that in the chamber intake gas line 25.

In addition, during a period until Transition step 2 starts or ends, the flow rate or the speed of the etching gas supplied from the gas supply unit 16 is adjusted and changed from Condition A to Condition B on the basis of the command from the control unit. At this time, the etching gas from the gas supply unit 16 is supplied to the first disposal gas line 23 similarly to Transition step 1. Further, as illustrated in FIG. 4, in Transition step 1, the processing chamber pressure and the microwave power changed to the values of the condition of Processing step A are changed to those of Processing step B in a period from the stating to the ending of Transition step 2.

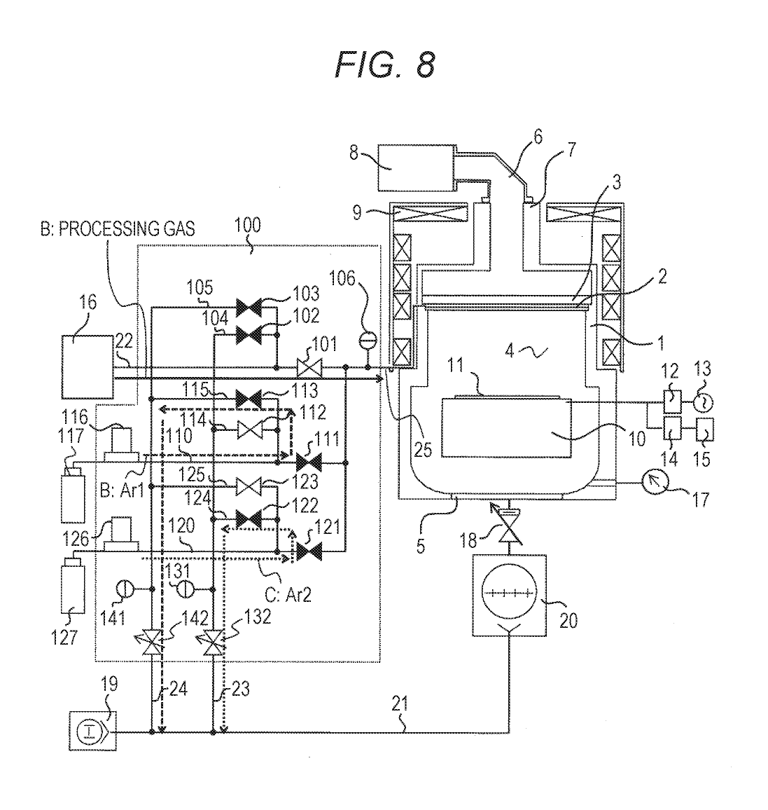

FIG. 8 illustrates a gas flow in the gas switching unit 100 of Processing step B. FIG. 8 is a diagram schematically illustrating a gas flow in Processing step B performed by the plasma processing apparatus according to the embodiment of FIG. 1. When the control unit detects or determines that a predetermined time elapses after Transition step 2 starts, the command signal from the control unit is transferred to the respective units of the plasma processing apparatus, so that Transition step 2 is stopped and Processing step B starts.

In this drawing, when Processing step B starts, the second valve 102 on the first gas supply line 22 is closed and the first valve 101 is opened on the basis of the command signal from the control unit. The etching gas of which the flow rate or the speed of Condition B is adjusted is supplied from the gas supply unit 16 to the processing chamber 4 through the chamber intake gas line 25. In addition, at the same time or substantially the same time, the seventh valve 121 is closed and the eighth valve 122 is opened in parallel, Argon gas 2 of which the flow rate or the speed is adjusted by the mass flow controller 126 for the second transition-step gas to be the same value or substantially equal to that of the etching gas used in Condition C which is a processing condition of Processing step C next to Processing step B is supplied to the first disposal gas line 23 through the third gas supply line 120 and the fifth bypass line 124.

Further, in Processing step B, the pressure in the second disposal gas line 24 to which Argon gas 1 is supplied after the flow rate or the speed is adjusted to be the same or similar value to that of Processing step B is adjusted to be the same value as that of the pressure gauge 106 for the chamber intake gas line by adjusting the operation of the variable conductance valve 142 on the basis of the command signal from the control unit according to the value detected by using the sensing result of the pressure gauge 141 for the second disposal gas line. In addition, other processing conditions such as the microwave power and the wafer bias power are adjusted on the basis of the command signal from the control unit to be equal to those of Condition B. The plasma is generated in the processing chamber 4, and the etching process of Processing step B is performed until the control unit detects that the processing reaches the end on the basis of the sensing result of the end-point determination unit.

In a case where there are Processing step C and the transition step toward Processing step C after Processing step B, as described above, the processing step is performed as long as needed by interposing Transition step 1 in which the condition is adjusted to be similar to that of the former processing step and the rare gas is supplied and Transition step 2 in which the condition is adjusted to be similar to that of the later processing step and the rare gas is introduced.

In the processing of the wafer 11 in which a plurality of processing steps having different processing conditions are performed by the plasma processing apparatus equipped with the above configuration, a time taken until the processing condition is changed and stabilized is reduced, and a throughput of the processes is improved. Furthermore, the reproducibility of a profile of the transient response of each condition in a so-called transient response time taken until the setting value starts to be changed to a value of an actual condition after receiving a command signal of the changing or until the value becomes a magnitude within a predetermined allowable fluctuation range is improved. The machine differences of such a transient response are reduced, and a throughput of processes is improved.

Further, in the above embodiment, the pressure in the exhaust line 21 is remarkably smaller than the pressure in the first and second disposal gas lines 23 and 24 (that is, the pressure in the chamber intake gas line 25) connected to one end of the exhaust line. In addition, the flow rate or the speed of the exhaust gas is adjusted to maintain the pressure in the processing chamber 4 in Conditions A and B. Therefore, even if the gas flows into at a predetermined flow rate or a speed from the first and second disposal gas lines 23 and 24, it is possible to suppress significant fluctuation from occurring in the pressure, the flow rate, or the speed in the gas lines.

Further, the invention is not limited to the above embodiment, and various modifications can be made. For example, in Transition steps 1 and 2 described using FIGS. 6 and 7, the plasma is generated in the processing chamber 4 using Argon gases 1 and 2, the wafer bias power is stopped, and the processing of the wafer 11 is suppressed. On the other hand, the plasma may be extinguished in Transition steps 1 and 2 and the processing may be stopped. Only the setting value of the microwave power may be changed, and not be introduced into the processing chamber 4 through the waveguide pipe 6.

In addition, in the above embodiment, two bypass lines and three valves are disposed between the etching gas supply line 22, the second gas supply line 110, and the third gas supply line 120, and between a chamber intake gas line 25, and the first disposal gas line 23, the second disposal gas line 24. Each line is opened or air-tightly closed according to the command signal from the control unit. The connection between the chamber intake gas line 25 and each supply line and the connection between each supply line and each disposal gas line are switched. These three valves may be configured by using few valves, for example, four-way valves. In this case, at least any one of the etching gas supply line 22, the second gas supply line 110, and the third gas supply line 120 may be additionally provided with valves which open and air-tightly close the gas circulation of three supply lines between each supply line and the chamber intake gas line 25.

Further, the etching gas used in Processing steps A and B may be configured using different types of materials and compositions, may be configured by the same type and composition while having different conditions in the flow rate or the speed, or may be different only in one of the type and the composition. In addition, the type of the using rare gas may be different from those in Transition steps 1 and 2. The embodiments are described in a clearly understandable way for the invention, and thus the invention is not necessarily to provide all the configurations described above.

1. A plasma processing apparatus, comprising:
a processing chamber that is disposed in a vacuum vessel;
a gas supply unit that supplies a predetermined amount of processing gas into the processing chamber; and
a sample table that is disposed in the processing chamber and in which a processing target wafer is placed on an upper surface thereof,
wherein the wafer is processed in a procedure which includes a plurality of processing steps to generate plasma in the processing chamber using the processing gas supplied in different conditions,
wherein the procedure includes a transition step in which a rare gas is supplied into the processing chamber between two former and later processing steps, and
wherein the transition step includes a first transition step in which the rare gas is supplied by being adjusted such that a pressure of the rare gas comes to be equal to a condition of the processing gas used in the former processing step, and a second transition step in which the rare gas is supplied by being adjusted after the first transition step such that a pressure and a flow rate of the rare gas come to be equal to a condition of the processing gas used in the later processing step.

2. The plasma processing apparatus according to claim 1,
wherein the gas supply unit includes
a gas intake line that is linked to the vacuum vessel,
a first gas supply line that is connected to the gas intake line and supplies the processing gas used in the plurality of processing steps,
second and third gas supply lines that supplies the rare gas used in each of the first and second transition steps,
first and second disposal gas lines that are connected to the first, second, and third gas supply lines and connected to an exhaust pump,
at least one valve that opens and closes connection between the first, second, and third gas supply lines and the gas intake line and between the first and second disposal gas lines, and
a control unit that switches the valve according to two processing steps of the procedure and the first and second transition steps between the two processing steps.

3. The plasma processing apparatus according to claim 2,
wherein the control unit adjusts an operation of the valve such that the rare gas is supplied to the first disposal gas line on a condition that the rare gas is used in the first transition step during the former processing step, and the rare gas is supplied to the second disposal gas line on a condition that the rare gas is used in the second transition step during the former transition step.

4. The plasma processing apparatus according to claim 1, further comprising:
first and second adjustment valves that are respectively disposed on the first and second disposal gas lines and adjust a pressure of the gas circulating in the inner portion.

5. A plasma processing method in which a procedure containing a plurality of processing steps in which a predetermined amount of processing gas is supplied into a processing chamber disposed in a vacuum vessel through a gas supply unit, and a processing target wafer placed on an upper surface of a sample table disposed in the processing chamber is processed by generating plasma in the processing chamber using the processing gas supplied on each different condition,
wherein the procedure includes a transition step in which a rare gas is supplied into the processing chamber between two former and later processing steps, and
wherein the transition step includes a first transition step in which the rare gas is adjusted and supplied such that a pressure of the rare gas comes to be equal to a condition of the processing gas used in the former processing step, and a second transition step in which the rare gas is adjusted and supplied after the first transition step such that a pressure and a flow rate of the rare gas come to be equal to a condition of the processing gas used in the later processing step.

6. A plasma processing method according to claim 5,
wherein the gas supply unit includes
a gas intake line that is linked to the vacuum vessel,
a first gas supply line that is connected to the gas intake line and supplies the processing gas used in the plurality of processing steps,
second and third gas supply lines that supplies the rare gas used in each of the first and second transition steps,
first and second disposal gas lines that are connected to the first, second, and third gas supply lines and connected to an exhaust pump, and
at least one valve that opens and closes connection between the first, second, and third gas supply lines and the gas intake line and between the first and second disposal gas lines, and
wherein the valve is switched according to two processing steps of the procedure and the first and second transition steps between the two processing steps to process the wafer.

7. The plasma processing method according to claim 5,
wherein the rare gas is supplied to the first disposal gas line in the former processing step on a condition that the rare gas is used in the first transition step, and
wherein the rare gas is supplied to the second disposal gas line in the first transition step on a condition that the rare gas is used in the second transition step.
